(19) United States
(12) Patent Application Publication
(10) Pub. No.: US 2009/0009434 A1
(43) Pub. Date: Jan. 8, 2009

(54) High power address driver and display device employing the same

(76) Inventors: Yong-Don Kim, Hwaseong-si (KR); Joung-Ho Kim, Suwon-si (KR); Mueng-Ryul Lee, Seoul (KR); Yong-Chan Kim, Suwon-si (KR); Sun-Hak Lee, Anyang-si (KR)

Correspondence Address: LEE & MORSE, P.C., 3141 FAIRVIEW PARK DRIVE, SUITE 500, FALLS CHURCH, VA, 22042, US

(21) Appl. No.: 12/213,936

(22) Filed: Jun. 26, 2008

(30) Foreign Application Priority Data
Jul. 3, 2007 (KR) 10-2007-0066705

(51) Int. Cl. G09G 3/28; H03K 19/094; G09G 5/00

(52) U.S. Cl. 345/60; 326/83; 345/204; 438/275

(57) ABSTRACT

An address driver includes an energy recovery circuit and an output stage connected to the energy recovery circuit. The output stage is connected to the energy recovery circuit and is formed of a pull-up MOS transistor and a pull-down MOS transistor in series. A source terminal of the pull-up MOS transistor is connected to the energy recovery circuit, and a bulk terminal of the pull-up MOS transistor is connected to a node providing a reverse bias between the source terminal and the bulk terminal of the pull-up MOS transistor. A display device employing the address driver is also provided.

### BACKGROUND OF THE INVENTION

1. Field of the Invention

Embodiments relate to a display device, and more particularly, to a high power address driver and a display device employing the same.

2. Description of the Related Art

Recently, alternatives for cathode ray tube (CRT) displays have been rapidly developed. Such alternatives include flat panel display devices that may be widely employed, e.g., in high performance TV sets and computer monitors. The flat panel display devices typically include a display panel and a display controller driving the display panel. Furthermore, flat panel display devices include an address driver and a scanning driver for two-dimensionally scanning output signals of the display controller to the display panel. These display panels may be classified according to the display mechanism employed therein, for example, as liquid crystal display (LCD) panels and plasma display panels (PDPs).

FIG. 1 illustrates a block diagram of an energy recovery circuit output stage of a conventional address driver and a display panel connected to the address driver.

Referring to FIG. 1, an output stage OST′ of the conventional address driver includes a pull-up transistor TP and a pull-down transistor TN, which are serially connected to each other. The pull-up transistor TP may be a high power p-channel metal-oxide-semiconductor (PMOS) transistor, and the pull-down transistor TN may be a high-power n-channel metal-oxide-semiconductor (NMOS) transistor. A drain region of the pull-down transistor TN is electrically connected with a drain region of the pull-up transistor TP so as to provide an output terminal OT of the output stage OST′ of the address driver. The output terminal OT is connected to a display panel DP′.

A source region of the pull-up transistor TP is electrically connected with an output terminal of an energy recovery circuit ERC′ by a node N, and a source region of the pull-down transistor TN is electrically connected to a ground terminal. Also, the source region of the pull-up transistor TP is directly connected to a bulk region (i.e., a channel body) of the pull-up transistor TP, and the source region of the pull-down transistor TN is directly connected to a bulk region (i.e., a channel body) of the pull-down transistor.

When the energy recovery circuit ERC′ is operated in a charging mode or a discharging mode, low-level signals (e.g., ground voltages) are applied to gate electrodes of the pull-up transistor TP and the pull-down transistor TN. As a result, the pull-up transistor TP is turned on, and the pull-down transistor TN is turned off.

A voltage V_{N} induced into the node N is higher than a voltage Vout of the output terminal OT in the charging mode, and the node voltage V_{N} is lower than the output voltage Vout in the discharging mode. Thus, a charge current I_{CG} is provided to the display panel DP′ through the pull-up transistor TP in the charging mode, and a discharge current I_{DG} flows to the energy recovery circuit ERC′ from o the display panel DP′ through the pull-up transistor TP in the discharging mode.

FIG. 2 illustrates a cross-sectional view of the pull-up transistor TP employed in the output stage of the address driver of FIG. 1.

Referring to FIG. 2, an n-type buried layer 2, which is heavily doped with an n-type impurity, is provided on a p-type semiconductor substrate 1, and an n-type epitaxial layer 3, which is lightly doped with an n-type impurity, is provided on the n-type buried layer 2. A field oxide layer 5 is provided in a predetermined region of the n-type epitaxial layer 3, thereby defining source and drain active regions 5s and 5d, which are spaced apart from each other. A p-type source region 7s and an n-type bulk pick-up region 7b, which are adjacent to each other, are provided in the source active region 5s, and a p-type heavily-doped drain region 7d is provided in the drain active region 5d. The p-type source region 7s and the n-type bulk pick-up region 7b are surrounded by an n-type source-side body region 9b, and the p-type heavily-doped drain region 7d is surrounded by a p-type lightly-doped drain region 9d. The p-type heavily-doped drain region 7d and the p-type lightly-doped drain region 9d constitute a p-type drain region 10d. The p-type lightly-doped drain region 9d contributes to increase a junction breakdown voltage of the p-type drain region 10d.

A gate electrode 11 is disposed on the field oxide layer 5 between the source active region 5s and the drain active region 5d. Consequently, the field oxide layer 5 disposed between the source active region 5s and the drain active region 5d serves as a gate oxide layer.

In the conventional pull-up transistor TP described above, the p-type drain region 10d, the n-type epitaxial layer 3 and the p-type semiconductor substrate 1 constitute a parasitic bipolar transistor BJT. That is, the p-type drain region 10d, the n-type epitaxial layer 3 and the p-type semiconductor substrate 1 correspond to an emitter region E, a base region B and a collector region C of the parasitic bipolar transistor BJT, respectively.

When the pull-up transistor TP is operated in the discharging mode, the discharge current I_{DG} described with reference to FIG. 1 may correspond to the sum of a channel discharge current I_{CH} and a bulk discharge current I_{B} as illustrated in FIG. 2. The channel discharge current I_{CH} flows to the energy recovery circuit ERC′ through the drain region 10d, the channel region under the gate electrode 11, and the source region 7s. The bulk discharge current I_{B} flows to the energy recovery circuit ERC′ through the drain region 10d, the n-type epitaxial layer 3, the n-type buried layer 2, and the n-type bulk pick-up region 7b. In this case, the bulk discharge current I_{B} may serve as a base current to turn on the parasitic bipolar transistor BJT. That is, in the discharging mode, the discharge current I_{DG} may further include a collector current I_{C} of the parasitic bipolar transistor BJT in addition to the channel discharge current I_{CH} and the bulk discharge current I_{B}. The collector current I_{C} corresponds to a parasitic current flowing toward a ground terminal through the p-type semiconductor substrate 1. Thus, when the parasitic current I_{C} flows, the discharge current I_{DG} may increase, and an electrical potential of the p-type semiconductor substrate 1 may be unstable. Consequently, the parasitic current I_{C} may increase power consumption of the address driver, i.e., the output stage OST′, and may cause malfunction of other discrete devices formed on the p-type semiconductor substrate 1.

To suppress the operation of the parasitic bipolar transistor BJT, current gain of the parasitic bipolar transistor BJT has to be lowered. To this end, as illustrated in FIG. 2, the n-type buried layer 2 having a higher impurity concentration than the n-type epitaxial layer 3 may be needed. Furthermore, in order to further lower the charge gain of the parasitic bipolar transistor BJT, an impurity concentration of the n-type epitaxial layer 3 has to be increased. However, as the impurity concentration of the n-type epitaxial layer 3 increases, a drain junction breakdown voltage of the pull-up transistor TP may be significantly decreased. Thus, there can be a limit to suppression of the operation of the parasitic bipolar transistor BJT.

### SUMMARY OF THE INVENTION

Embodiments are therefore directed to an address driver and a display device employing the same, which substantially overcome one or more of the disadvantages of the related art.

It is therefore a feature of an embodiment to provide an address driver suitable for suppressing an operation of a parasitic bipolar transistor and a display device employing the same.

At least one of the above and other features and advantages may be realized by providing an address driver including an energy recovery circuit and an output stage. The output stage is connected to the energy recovery circuit and is formed of a pull-up MOS transistor and a pull-down MOS transistor in series. A source terminal of the pull-up MOS transistor is connected to the energy recovery circuit, and a bulk terminal of the pull-up MOS transistor is connected to a node providing a reverse bias between the source terminal and the bulk terminal of the pull-up MOS transistor.

In some embodiments, the pull-up MOS transistor may be a p-channel MOS transistor, and the pull-down MOS transistor may be an n-channel MOS transistor. In this case, a drain terminal of the pull-up MOS transistor may be electrically connected to a drain terminal of the pull-down MOS transistor, thereby forming an output terminal of the output stage. Also, a source terminal of the pull-down MOS transistor may be grounded. Furthermore, the node connected to the bulk terminal of the pull-up MOS transistor may have a higher voltage than the source terminal of the pull-up MOS transistor. For example, an output voltage of a power source supplying electrical power to the energy recovery circuit may be higher than an output voltage of the energy recovery circuit, and the bulk terminal of the pull-up MOS transistor may be electrically connected to an output terminal of the power source through the node.

In other embodiments, the energy recovery circuit may include a resonance circuit connected to the energy recovery circuit.

At least one of the above and other features and advantages may be realized by providing an address driver in a semiconductor substrate. The address driver includes a pull-up MOS transistor, a pull-down MOS transistor and an energy recovery circuit in first to third regions of the semiconductor substrate, respectively. The pull-up MOS transistor and the pull-down MOS transistor are covered with an insulating layer. A first source interconnection and a first bulk interconnection are on the insulating layer. The first source interconnection is electrically connected to a source region of the pull-up MOS transistor, and the first bulk interconnection is electrically connected to a bulk region of the pull-up MOS transistor. The energy recovery circuit is electrically connected to the first source interconnection. The first bulk interconnection is electrically insulated from the first source interconnection.

In some embodiments, the address driver may be formed on the insulating layer, and may further include a power line supplying electrical power to the energy recovery circuit. In this case, the first bulk interconnection may be electrically connected to the power line.

In other embodiments, the pull-up MOS transistor and the pull-down MOS transistor may be a p-channel MOS transistor and an n-channel MOS transistor, respectively. In this case, the semiconductor substrate may include a p-type supporting substrate and an n-type body layer disposed on the p-type supporting substrate. The pull-up MOS transistor may include a p-type diffusion isolation region in a predetermined region of the n-type body layer and electrically isolating a part of the n-type body layer, a p-type drain region in the isolated n-type body layer, a p-type source region in the isolated n-type body layer and spaced apart from the p-type drain region; an n-type bulk pick-up region formed in the isolated n-type body layer between the p-type diffusion isolation region and the p-type source region, and the isolated n-type body layer between the p-type diffusion region and the p-type drain region, and a gate electrode on the isolated n-type body layer between the p-type source and drain regions. The first source interconnection may be electrically connected to the p-type source region through the insulating layer, and the first bulk interconnection may be electrically connected to the n-type bulk pick-up region through the insulating layer. Also, the p-type diffusion isolation region may be in contact with the p-type supporting substrate. An n-type buried layer may be interposed between the isolated n-type body layer and the p-type supporting substrate. The n-type buried layer may have a higher impurity concentration than the n-type body layer.

The pull-up MOS transistor may have a symmetrical structure with respect to a vertical axis passing through a central point of the isolated n-type body layer between the p-type source region and the p-type drain region. First and second drain interconnections may be on the insulating layer. The first and second drain interconnections may be electrically connected to the p-type drain region of the pull-up MOS transistor and the drain region of the pull-down MOS transistor, respectively. The first and second drain interconnections may be electrically connected to each other, and thus, may serve as an output terminal of the output stage formed of the pull-up MOS transistor and the pull-down MOS transistor.

At least one of the above and other features and advantages may be realized by providing a display device employing the address driver. The display device includes a display panel having a plurality of pixels two-dimensionally disposed along rows and columns, a scanning driver and an address driver configured to sequentially provide an image signal to the plurality of pixels, and a display controller configured to control the scanning driver and the address driver. The address driver includes an energy recovery circuit generating a charge or discharge signal in response to an output signal of the display controller and a plurality of output stages parallel-connected to the energy recovery circuit. Each output stage includes a pull-up MOS transistor and a pull-down MOS transistor serially connected to the energy recovery circuit. Each output stage includes an output terminal connected to one of the columns, a source terminal of the pull-up MOS transistor connected to the energy recovery circuit, and a bulk terminal of the pull-up MOS transistor connected to a node providing a reverse bias between the source terminal and the bulk terminal of the pull-up MOS transistor.

In some embodiments, the display device may be a plasma display panel.

At least one of the above and other features and advantages may be realized by providing a display device including a display panel having a plurality of pixels, and a scanning driver and an address driver sequentially providing a charge signal or a discharge signal to the plurality of pixels. The address driver includes an energy recovery circuit having a resonance circuit generating a charge or discharge signal, and a plurality of output stages parallel-connected the energy recovery circuit. Each output stage includes a pull-up MOS transistor on a semiconductor substrate and having a first source region electrically connected to the energy recovery circuit, a pull-down MOS transistor on the semiconductor substrate and having a second drain region electrically connected to a first drain region of the pull-up MOS transistor, an insulating layer covering the pull-up MOS transistor and the pull-down MOS transistor, a first source interconnection on the insulating layer and electrically connected to the first source region, and a first bulk interconnection fored on the insulating layer and electrically connected to the first bulk region of the pull-up MOS transistor. The first source interconnection is electrically insulated from the first bulk interconnection.

At least one of the above and other features and advantages may be realized by providing a method of making an address driver, including forming a pull-up MOS transistor in a first region of a semiconductor substrate, forming a pull-down MOS transistor in a second region of the semiconductor substrate, forming an insulating layer covering the pull-up MOS transistor and the pull-down MOS transistor, forming a first source interconnection on the insulating layer and electrically connected to a source region of the pull-up MOS transistor, forming a first bulk interconnection on the insulating layer and electrically connected to a bulk region of the pull-up MOS transistor, and forming an energy recovery circuit in a third region of the semiconductor substrate and being electrically connected to the first source interconnection, wherein the first bulk interconnection is electrically insulated from the first source interconnection.

### BRIEF DESCRIPTION OF THE DRAWINGS

The above and other features and advantages will become more apparent to those of ordinary skill in the art by describing in detail exemplary embodiments thereof with reference to the attached drawings, in which:

FIG. 1 illustrates a block diagram of a conventional high power address driver and a display panel connected thereto;

FIG. 2 illustrates a cross-sectional view of a pull-up transistor employed to an output stage of the high power address driver of FIG. 1;

FIG. 3 illustrates a schematic block diagram of a display device according to an embodiments;

FIG. 4 illustrates an equivalent circuit diagram of the address driver of FIG. 3 and a power source connected thereto;

FIG. 5 illustrates a waveform of output signals of the address driver of FIG. 4;

FIG. 6 illustrates a plan view of a pull-up transistor employed to the output stage of the address driver of FIG. 4;

FIG. 7 illustrates a plan view of a pull-down transistor employed to the output stage of the address driver of FIG. 4;

FIG. 8 illustrates a cross-sectional view taken along line VIII-VIII′ of FIG. 6; and

FIG. 9 illustrates a cross-sectional view taken along line IX-IX′ of FIG. 7.

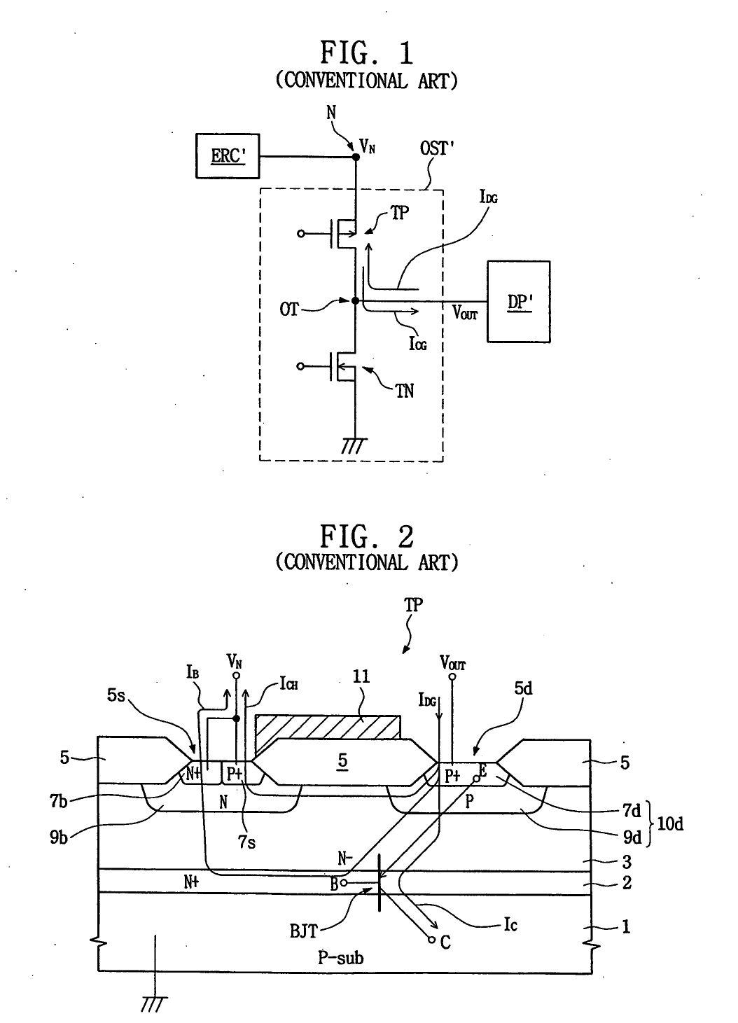

### DETAILED DESCRIPTION OF THE INVENTION

Korean Patent Application No. 10-2007-0066705, filed on Jul. 3, 2007, in the Korean Intellectual Property Office, and entitled: “High Power Address Driver and Display Device Employing the Same,” is incorporated by reference herein in its entirety.

Embodiments will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions may be exaggerated for clarity. In addition, when a layer is described to be formed on another layer or on a substrate, the layer may be formed directly on the other layer or on the substrate, or a third layer may be interposed between the layer and the other layer or the substrate. Like numbers may refer to like elements throughout the specification.

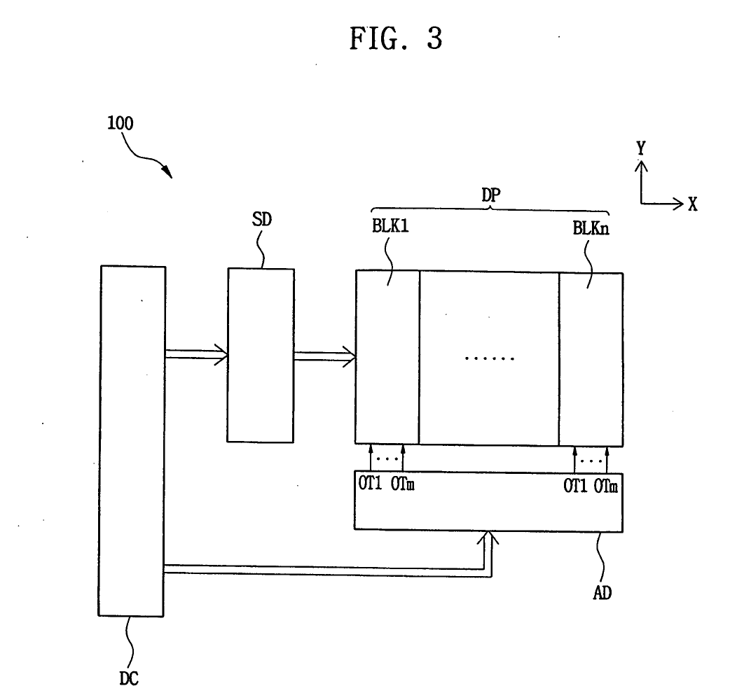

FIG. 3 illustrates a schematic block diagram of a display device employing an address driver according to an exemplary embodiment.

Referring to FIG. 3, a display device 100 may include a display panel DP, an address driver AD and a scanning driver SD, which are connected to the display panel DP, and a display controller DC controlling the address driver AD and the scanning driver SD. The display panel DP may include a plurality of pixel blocks, for example, first to n-th pixel blocks BLK1, . . . , and BLKn, which may be sequentially disposed in one direction, e.g., along an x axis direction.

Each pixel block BLK1, . . . , BLKn may include a plurality of pixels, which may be arranged in a two-dimensional array. That is, the pixels in the pixel block BLK1, . . . , or BLKn may be disposed at intersecting points of a plurality of rows parallel to the x axis and first to m-th columns parallel to a y axis crossing the x axis.

The address driver AD may provide image data by selecting one of the first to m-th columns in the pixel block BLK1, . . . , or BLKn, and the scanning driver SD may sequentially select the rows. As a result, the address driver AD may include first to m-th output terminals OP1, . . . , OPm respectively connected to the first to m-th columns in each pixel block BLK1, . . . , or BLKn. When the display panel DP is a plasma display panel (PDP), the image data, i.e., an output signal of the address driver AD, may be a charge or discharge signal controlling plasma of the pixel connected to the selected column. The address driver AD may include a plurality of address drivers respectively connected to the plurality of pixel blocks BLK1, . . . , BLKn.

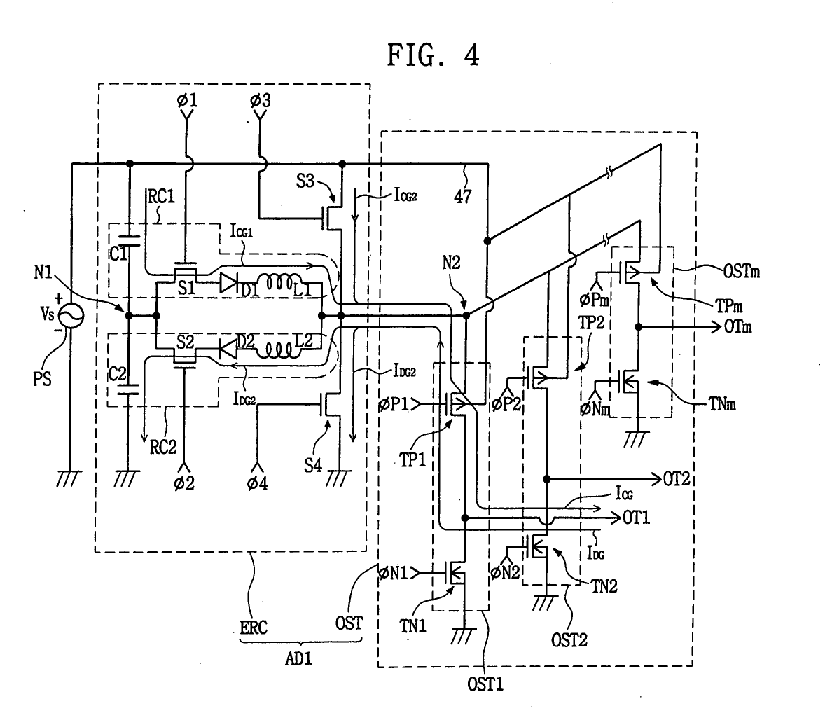

FIG. 4 illustrates an equivalent circuit diagram of a first address driver AD1 and a power source PS connected thereto, which may serve as the address driver AD of FIG. 3.

Referring to FIG. 4, the first address driver AD1 may include an energy recovery circuit ERC and an output stage OST connected thereto. The energy recovery circuit ERC may include a first resonance circuit RC1 generating a charge signal and a second resonance circuit RC2 generating a discharge signal.

The first resonance circuit RC1 may include a first capacitor C1, a first switching device S1, a first diode D1, and a first inductor L1, which are serially connected to each other. The first switching device S1 may be a first MOS transistor. A first electrode of the first capacitor C1 may be connected to one of source and drain terminals of the first MOS transistor S1, and the other of the source and drain terminals of the first MOS transistor S1 may be connected to an anode of the first diode D1. A cathode of the first diode D1 may be connected to a first electrode of the first inductor L1.

The second resonance circuit RC2 may include a second capacitor C2, a second switching device S2, a second diode D2, and a second inductor L2, which are serially connected to each other. The second switching device S2 may be a second MOS transistor. A first electrode of the second capacitor C2 may be connected to one of source and drain terminals of the second MOS transistor S2, and the other of the source and drain terminals of the second MOS transistor S2 may be connected to a cathode of the second diode D2. An anode of the second diode D2 is connected to a first electrode of the second inductor L2.

The first electrodes of the first and second capacitors C1 and C2 may be electrically connected to each other, thereby constituting a first node N1. Second electrodes of the first and second inductors L1 and L2 may be electrically connected to each other, thereby constituting a second node N2. The first MOS transistor S1 may be turned on or off in response to a first signal Φ1 generated from output signals of the display controller DC. The second MOS transistor S2 may be turned on or off in response to a second signal Φ2 generated from output signals of the display controller DC. The first and second signals Φ1 and Φ2 may be applied to a gate electrode of the first MOS transistor S1 and a gate electrode of the second MOS transistor S2, respectively.

A second electrode of the first capacitor C1 may be connected to an output terminal of the power source PS, which supplies electrical power to the first and second resonance circuits RC1 and RC2. A second electrode of the second capacitor C2 may be grounded. The power source PS may be a system power source which supplies electrical power to the display device of FIG. 3.

The energy recovery circuit ERC may include a third switching device S3 and a fourth switching device S4 parallel-connected to the second node N2. The third and fourth switching devices S3 and S4 may be third and fourth MOS transistors, respectively. A source terminal of the third MOS transistor S3 and a drain terminal of the fourth MOS transistor S4 may be connected to the second node N2. A drain terminal of the third MOS transistor S3 and a source terminal of the fourth MOS transistor S4 may be connected to an output terminal and a ground terminal of the power source PS, respectively. The third and fourth MOS transistors S3 and S4 may be controlled by third and fourth signals Φ3 and Φ4 generated from the output signals of the display controller DC, respectively. That is, the third and fourth signals Φ3 and Φ4 may be applied to gate electrodes of the third and fourth MOS transistors S3 and S4, respectively.

The output stage OST may include a plurality of output stages parallel-connected to the second node N2, e.g., first to m-th output stages OST1, . . . , OSTm. Each of the first to m-th output stages OST1, . . . , OSTm may include a pull-up transistor and a pull-down transistor serially connected to the second node N2. For example, the first output stage OST1 may include a first pull-up MOS transistor TP1 connected to the second node N2 and a first pull-down MOS transistor TN1 connected to the first pull-up MOS transistor TP1. The first pull-up MOS transistor TP1 and the first pull-down MOS transistor TN1 may be a p-channel MOS (PMOS) transistor and an n-channel MOS (NMOS) transistor, respectively. A source terminal of the first pull-up MOS transistor TP1 may be connected to the second node N2. Drain terminals of the first pull-up MOS transistor TP1 and the pull-down MOS transistor TN1 may be connected to each other, thereby constituting an output terminal OT1 of the first output stage OST1.

Each of the second to m output stages OST2, . . . , OSTm may have the same configuration as the first output stage OST1. That is, the second output stage OST2 may include a second pull-up MOS transistor TS2 and a second pull-down MOS transistor TN2 serially connected to the second node N2, and the m-th output stage OSTm may include an m-th pull-up MOS transistor TPm and an m-th pull-down MOS transistor TNm serially connected to the second node N2. Also, a drain terminal of the second pull-up MOS transistor TP2 and a drain terminal of the second pull-down MOS transistor TN2 may be electrically connected to each other, thereby constituting an output terminal OT2 of the second output stage OST2, and a drain terminal of the m-th pull-up MOS transistor TPm and a drain terminal of the m-th pull-down MOS transistor TNm may be electrically connected to each other, thereby constituting an output terminal OTm of the m-th output stage OSTm. The first to m-th output terminals OT1, . . . , OTm may be connected to the first to m-th columns of one of the pixel blocks LBLK1, . . . , BLKn illustrated with reference to FIG. 3, respectively.

Source and bulk terminals of the first to m-th pull-down MOS transistors TN1, . . . , TNm may be configured to have the same potential. For example, all of the source and bulk terminals of the first to m-th pull-down MOS transistors TN1, . . . , TNm may be grounded. Additionally, bulk terminals of the first to m-th pull-up MOS transistors TP1, . . . , TPm may be connected to a node having a different potential from source terminals (i.e., the second node N2) of the pull-up MOS transistors TP1, . . . , TPm. For example, the bulk terminals of the pull-up MOS transistors TP1, . . . , TPm may be configured to apply a reverse bias between the source terminals and the bulk terminals of the pull-up MOS transistors TP1, . . . , TPm. Particularly, when the pull-up MOS transistors TP1, . . . , TPm are PMOS transistors, the bulk terminals of the pull-up MOS transistors TP1, . . . , TPm may be connected to a third node having a higher voltage than the source terminals (i.e., higher then the voltage of the second node N2) of the pull-up MOS transistors TP1, . . . , TPm.

In an embodiment, when an output voltage Vs of the power source PS is higher than a voltage induced into the second node N2, the bulk terminals of the pull-up MOS transistors TP1, . . . , TPm may be connected to the output terminal of the power source PS via a power line 47. However, the present invention is not limited to the embodiment described above, and may be modified in various forms. For example, the bulk terminals of the pull-up MOS transistors TP1, . . . , TPm may be connected to any node having a higher voltage than the voltage at the second node N2.

The first to m-th pull-up MOS transistors TP1, . . . , TPm may be turned on or off in response to first to m-th pull-up signals ΦP1, . . . , ΦPm generated by the output signals of the display controller DC, respectively. The first to m-th pull-down MOS transistors TN1, . . . , TNm may be turned on or off in response to first to m-th pull-down signals ΦN1, . . . , ΦNm generated by the output signals of the display controller DC, respectively.

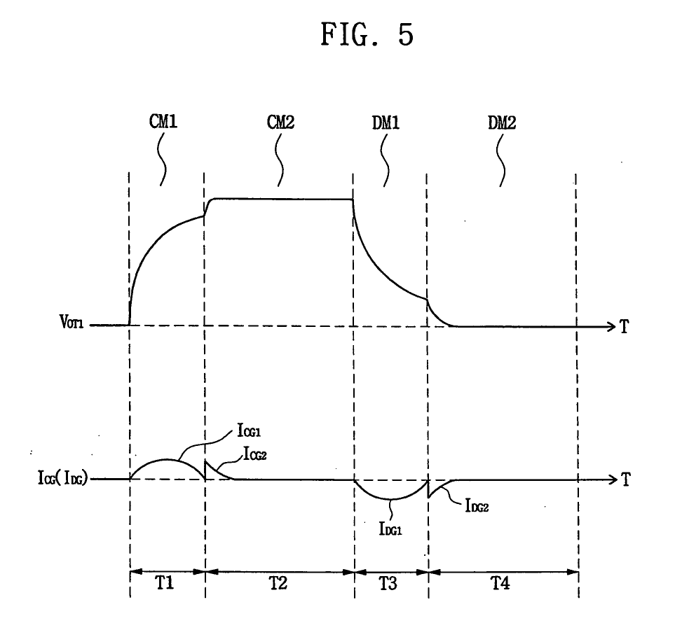

The operation of the first address driver AD1 of FIG. 4 will now be described with reference to FIG. 5.

FIG. 5 illustrates a waveform of output signals of the first address driver AD1 of FIG. 4 over time T. Here, the operation of the first address driver AD1 will be described with reference to only output signals of the first output stage OST1 among the output stages constituting the first address driver AD1 for convenience of explanation. The output signals may correspond to a first output voltage V_{OT1}, a charge current I_{CG} and a discharge current I_{DG}.

Referring to FIGS. 4 and 5, in order to provide a charge signal to pixels connected to a first output terminal OT1 of the first output stage OST1 (pixels connected to one of the columns of the display panel DP of FIG. 3), the first switching device S1 and the first pull-up MOS transistor TP1 are turned on for a first time period T1. In this case, the second to fourth switching devices S2, S3 and S4 and the first pull-down MOS transistor TN1 are turned off. As a result, a first resonance circuit RC1 connected to the power source PS generates a first charge current I_{CG1}, which flows toward the display panel DP through the second node N2, the first pull-up MOS transistor TP1, and the first output terminal OT1. While the first charge current I_{CG1} flows, a first output voltage V_{OT1} induced into the first output terminal OT1 gradually increases. An operation state in which the first charge current I_{CG1} flows is referred to as “a first charging mode CM1.” In the first charging mode, the first output voltage V_{OT1} may be determined by the first time period T1.

After the first time period T1, the third switching device S3 may be turned on for a second time period T2. The first switching device S1 may remain turned on for the second time period T2. As a result, a second charge current I_{CG2} flows through the third switching device S3 and the first pull-up MOS transistor TP1. Thus, the first output voltage V_{OT1} may further increase. An operation state in which the second charge current I_{CG2} flows is referred to as “a second charging mode CM2.”

After the second time period T2, the first and third switching devices S1 and S3 are turned off, and the second switching device S2 is turned on for a third time period T3. As a result, a first discharge current I_{DG1} flows through the first pull-up MOS transistor TP1 and the second resonance circuit RC2 from a pixel charged by the first and second charge currents I_{CG1} and I_{CG2}, i.e., the charge current I_{CG}. The first output voltage V_{OT1} gradually decreases while the first discharge current I_{DG1} flows. An operation state in which the first discharge current I_{DG1} flows is referred to as “a first discharging mode DM1.” In the first discharging mode DM1, the first discharge voltage V_{OT1} may be determined by the third time period T3.

After the third time period T3, the fourth switching device S4 may be turned on for a fourth period of time T4. In this case, the second switching device S2 may still be turned on for the fourth period of time T4. As a result, a second discharge current I_{DG2} may flow through the fourth switching device S4 and the first pull-up MOS transistor TP1. Thus, the first output voltage V_{OT1} may be further reduced. An operation state in which the second discharge current I_{DG2} flows is referred to as “a second discharging mode DM2.” In the second discharging mode DM2, the first output voltage V_{OT1} may be determined by the fourth time period T4.

During the aforementioned charge/discharge operations, the scanning driver SD of FIG. 3 may also be operated. That is, the scanning driver SD may include a plurality of scanning output terminals for sequentially selecting pixels connected to the first output terminals OST1. Thus, data output from a pixel of the pixels connected to the first output terminal OST1 (for example, a color of light and/or contrast) may be determined by a voltage difference between the scanning output terminal connected to the selected pixel and the first output terminal OT1.

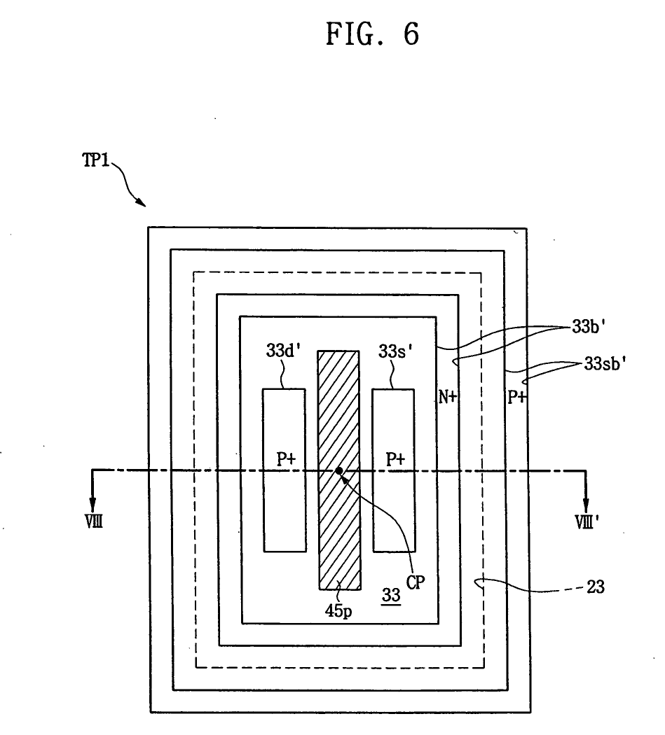

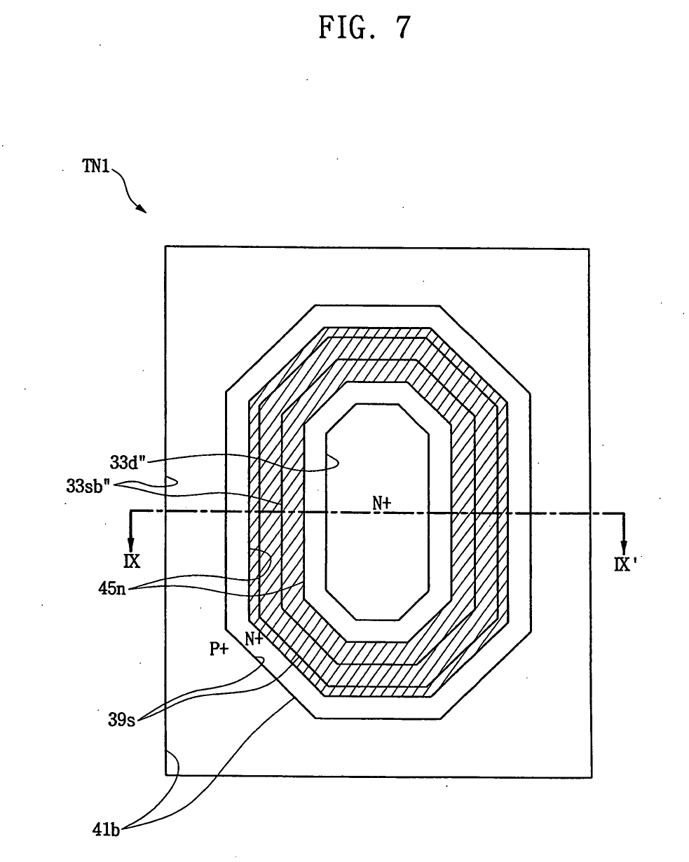

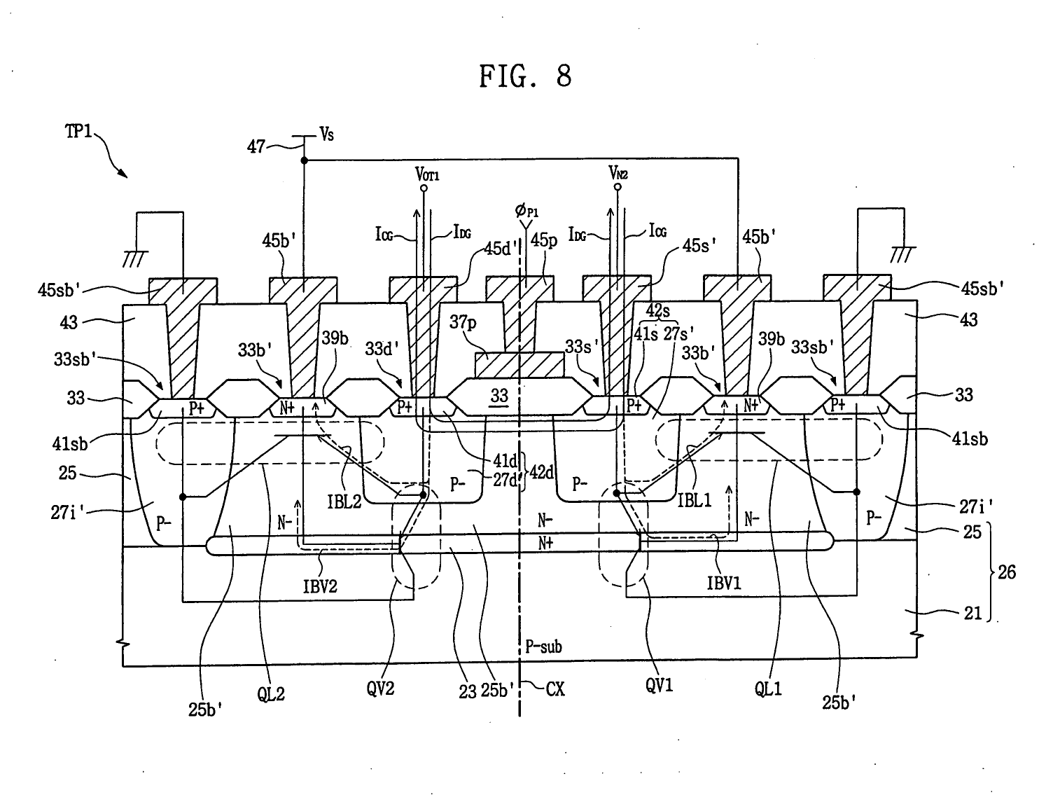

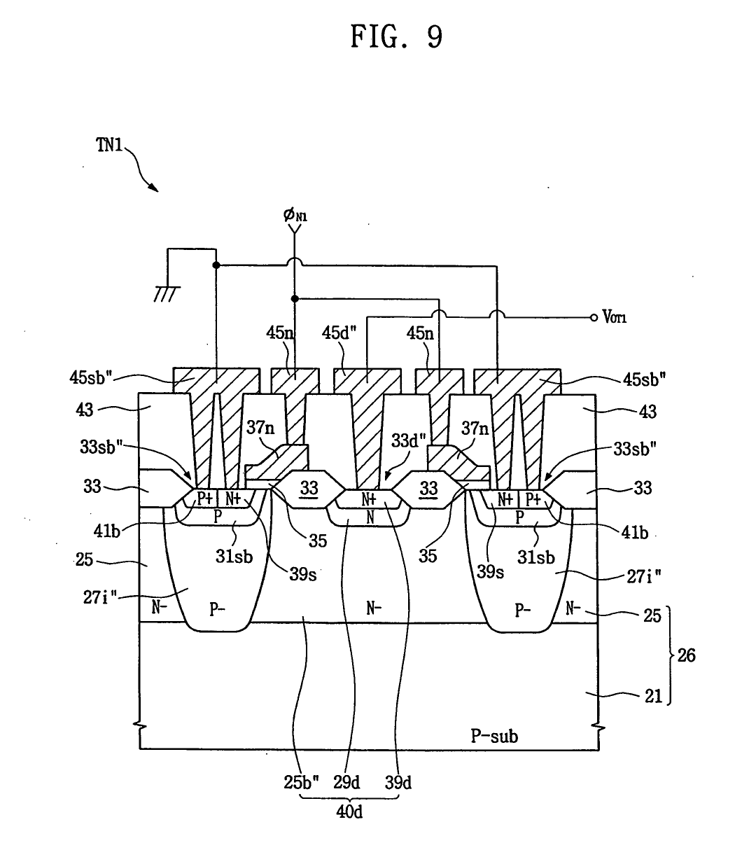

FIG. 6 illustrates a plan view of the first pull-up MOS transistor TP1 of FIG. 4, and FIG. 7 illustrates a plan view of the first pull-down MOS transistor TN1 of FIG. 4. FIG. 8 is illustrates cross-sectional view taken along line VIII-VIII′ of FIG. 6, and FIG. 9 illustrates a cross-sectional view taken along line IX-IX′ of FIG. 7.

Referring to FIGS. 6 and 8, the pull-up MOS transistor TP1, i.e., a PMOS transistor, may be provided in a first region of a semiconductor substrate 26 including a substrate 21 of a first conductivity type and a body layer 25 of a second conductivity type stacked on the substrate 21. The first and second conductivity types may be a p-type and an n-type, respectively. A diffusion isolation region 27i′ of the first conductivity type may be provided in a predetermined region of the body layer 25.

The diffusion isolation region 27i′ may have a closed shape, e.g. a rectangular shape, when seen from the plan view, and may contact the supporting substrate 21 through the body layer 25. Thus, the diffusion isolation region 27i′ may electrically isolate a part 25b′. of the body layer 25. Also, a substrate pick-up region 41sb of the first conductivity type may be provided on the surface of the diffusion isolation region 27i′. The substrate pick-up region 41sb may have a higher impurity concentration than the diffusion isolation region 27i′.

A buried layer 23 of the second conductivity type may be further provided between the isolated body layer 25b′ and the supporting substrate 21. The buried layer 23 may have a higher impurity concentration than the body layer 25.

A lightly-doped source region 27s′ and a lightly-doped drain region 27d′, spaced apart from each other, may be provided in the isolated body layer 25b′. The lightly-doped source and drain regions 27s′ and 27d′ may have the first conductivity type and may be separated from the buried layer 23. In an embodiment, the lightly-doped source and drain regions 27′s and 27d′ and the diffusion isolation region 27i′ may be simultaneously formed by the same process, e.g., an ion injection process. In this case, the lightly-doped source and drain regions 27s′ and 27d′ may be in contact with the buried layer 23.

A heavily-doped source region 41s and a heavily-doped drain region 41d may be provided in the lightly-doped source region 27s′ and the lightly-doped drain region 27d′, respectively. The heavily-doped source and drain regions 41s and 41d have the same conductivity type as the lightly-doped source and drain regions 27s′ and 27d′. The lightly-doped source region 27s′ and the heavily-doped source region 41s constitute a source region 42s, and the lightly-doped drain region 27d′ and the heavily-doped drain region 41d constitute a drain region 42d.

Bulk pick-up regions 39b of the second conductivity type may be provided in the isolated body layer 25b′, between the source region 42s and the adjacent diffusion isolation region 27i′, and in the isolated body layer 25b′, between the drain region 42d and the adjacent diffusion isolation region 27i′. The bulk pick-up region 39b may have a higher impurity concentration than the body layer 25.

A field insulating layer 33, e.g., a field oxide layer, defining a plurality of active regions may be provided in predetermined regions of the body layer 25 and the isolated body layer 25b′. The active regions may include a source active region 33s′, a drain active region 33d′, a bulk active region 33b′ and a substrate active region 33sb′. The heavily-doped source region 41s, the heavily-doped drain region 41d, the bulk pick-up region 39b, and the substrate pick-up region 41sb may be provided in the source active region 33s′, the drain active region 33d′, the bulk active region 33b′, and the substrate active region 33sb′, respectively.

A gate electrode 37p may be disposed on the field insulating layer 33 between the heavily-doped source and drain regions 41s and 41d. An insulating layer 43 may be disposed on the gate electrode 37p, the active regions 33s′, 33d′, 33b′, and 33sb′, and the field insulating layer 33.

As illustrated in FIGS. 6 and 8, the first-pull-up MOS transistor TP1 may have a symmetrical structure with respect to a vertical axis CX passing through a central point CP in a channel region between the source region 42s and the drain region 42d.

A first source interconnection 45s′, a first drain interconnection 45d′, a first bulk interconnection 45b′, a first substrate interconnection 45sb′, and a first gate interconnection 45p may be disposed on the insulating layer 43. The first source interconnection 45s′ and the first drain interconnection 45d′ may pass through the insulating layer 43 to be electrically connected to the heavily-doped source region 41s and the heavily-doped drain region 41d, respectively. The first bulk interconnection 45b′ and the first substrate interconnection 45sb′ may pass through the insulating layer 43 to be electrically connected to the bulk pick-up region 39b and the substrate pick-up region 41sb, respectively. Also, the first gate interconnection 45p may pass through the insulating layer 43 to be electrically connected to the gate electrode 37p.

The first substrate interconnection 45sb′ may be connected to the ground terminal, and the first bulk interconnection 45b′ may be connected to the power source PS illustrated in FIG. 4 via the power line 47. The first source interconnection 45s′ may be connected to the second node N2 of FIG. 4, and the first drain interconnection 45d′ may be connected to the first output terminal OT1 of FIG. 4. Thus, in the charging and discharging modes CM1, CM2, DM1, and DM2 described with reference to FIGS. 4 and 5, a voltage V_{N2} induced into the second node N2 is applied to the first source interconnection 45s′, and a first output voltage V_{OT1} is applied to the first drain interconnection 45d′. Also, a power voltage Vs higher than the second node voltage V_{N2} may be applied to the first bulk interconnection 45b′. As a result, a reverse bias is applied between the source region 42s and the isolated body layer 25b′.

In the first pull-up MOS transistor TP1 illustrated in FIG. 8, the p-type source region 42s, the n-type buried layer 23 and the p-type semiconductor substrate 21 may constitute a first parasitic vertical bipolar transistor QV1. That is, the p-type source region 42s, the n-type buried layer 23 and the p-type semiconductor substrate 21 may correspond to an emitter region, a base region, and a collector region of the first parasitic vertical bipolar transistor QV1, respectively. Also, the p-type source region 42s, the n-type isolated body layer 25b′ and the p-type diffusion isolation region 27i′ may constitute a first parasitic horizontal bipolar transistor QL1. That is, the p-type source region 42s, the n-type isolated body layer 25b′ and the p-type diffusion isolation region 27i′ correspond to an emitter region, a base region, and a collector region of the first parasitic horizontal bipolar transistor QL1, respectively.

The p-type drain region 42d, the n-type buried layer 23, and the p-type semiconductor substrate 21 may constitute a second parasitic vertical bipolar transistor QV2. That is, the p-type drain region 42d, the n-type buried layer 23 and the p-type semiconductor substrate 21 may correspond to an emitter region, a base region, and a collector region of the second parasitic vertical bipolar transistor QV2, respectively. Further, the p-type drain region 42d, the n-type isolated body layer 25b′, and the p-type diffusion isolation region 27i′ may constitute a second parasitic horizontal bipolar transistor QL2. That is, the p-type drain region 42d, the n-type isolated body layer 25b′ and the p-type diffusion isolation region 27i′ may correspond to an emitter region, a base region, and a collector region of the second parasitic horizontal bipolar transistor QL2, respectively.

When the first pull-up MOS transistor TP1 is operated in the charging modes CM1 and CM2, the charge current I_{CG} of FIG. 4 flows toward the first drain interconnection 45d′ from the first source interconnection 45s′ through the channel region under the gate electrode 37p. In this case, no parasitic current flows into the n-type isolated body layer 25b′ from the p-type source region 42s. In other words, no base current IBL1 flows in the first parasitic horizontal bipolar transistor QL1. In this way, no parasitic current flows into the n-type buried layer 23 from the p-type source region 42s. That is, no base current IBV1 flows in the first parasitic vertical bipolar transistor QV1. This is because a reverse bias is applied between the source region 42s and the isolated body layer 25b′. As a result, the reverse bias applied between the source region 42s and the isolated body layer 25b′ represses operation of the first parasitic vertical and horizontal bipolar transistors QV1 and QL1, thus preventing or reducing generation of a leakage current in the charging modes CM1 and CM2.

When the first pull-up MOS transistor TP1 is operated in the discharging modes DM1 and DM2, the discharging current I_{DG} of FIG. 4 flows toward the first source interconnection 45s′ from the first drain interconnection 45d′ through the channel region under the gate electrode 37p as illustrated in FIG. 8. In this case, no parasitic current flows into the n-type isolated body layer 25b′ from the p-type drain region 42d. In other words, no base current IBL2 or IBV2 flows in the second parasitic horizontal or vertical bipolar transistor QL2 or QV2. This is because a reverse bias is applied between the source region 42s and the isolated body layer 25b′ as described above. As a result, the reverse bias applied between the source region 42s and the isolated body layer 25b′ represses operations of the second parasitic vertical and horizontal bipolar transistors QV2 and QL2, and thus prevents generation of a leakage current in the discharging modes DM1 and DM2.

Referring to FIGS. 7 and 9, the pull-down MOS transistor TN1, i.e., an NMOS transistor may be also provided to a second region of the semiconductor substrate 26 described with reference to FIGS. 6 and 8. A diffusion isolation region 27i″ of the first conductivity type, i.e., a p-type diffusion isolation region may be provided in a predetermined region of the body layer 25.

The diffusion isolation region 27i″ may have a closed loop shape when seen from the plan view, and may contact the supporting substrate 21 through the body layer 25. Thus, the diffusion isolation region 27i″ may electrically isolate a part 25b″ of the body layer 25. Further, a bulk region 31sb of the first conductivity type may be provided in the diffusion isolation region 27i″, and a heavily-doped drain region 39d of the second conductivity type may be provided in a predetermined region of the isolated body layer 25b″. Furthermore, a lightly-doped drain region 29d of the second conductivity type surrounding the heavily-doped drain region 39d may be provided in the isolated body layer 25b″. The isolated body layer 25b″, the lightly-doped drain region 29d, and the heavily-doped drain region 39d may constitute a drain region 40d of the pull-down MOS transistor TN1.

A source region 39s of the second conductivity type and a bulk pick-up region 41b of the first conductivity type may be provided on the surface of the bulk region 31sb. The source region 39s may be adjacent to the isolated body layer 25b″, and the bulk pick-up region 41b may be adjacent to the source region 39s and opposite to the isolated body layer 25b″. The bulk pick-up region 41b may have the same conductivity type (i.e., the first conductivity type) as the diffusion isolation region 27i″ and the bulk region 31sb. Thus, the bulk pick-up region 41b may serve as a substrate pick-up region.

The field insulating layer 33 described with reference to FIGS. 6 and 8 may define a drain active region 33d″ and a source/bulk active region 33sb″ in predetermined regions of the body layer 25 and the isolated body layer 25b″. In this case, the heavily-doped drain region 39d may be provided in the drain active region 33d″, and the source region 39s and the bulk pick-up region 41b may be provided in the source/bulk active region 33sb″. Also, the field insulating layer 33 between the heavily-doped drain region 39d and the source region 39s may be spaced apart from the source region 39s. That is, the diffusion isolation region 27i″ and the bulk region 31sb may be provided to extend to the surface of the source/bulk active region 33sb″ between the isolated body layer 25b″ and the source region 39s.

A gate insulating layer 35 may be provided on the source/bulk active region 33sb″ between the isolated body layer 25b″ and the source region 39s, and a gate electrode 37n may be disposed on the gate insulating layer 35. The gate electrode 37n may extend to cover the field insulating layer 33 on the isolated body layer 25b″.

The insulating layer 43 described with reference to FIGS. 6 and 8 may cover the gate electrode 37n, the field insulating layer 33, the drain active region 33d″, and the source/bulk active region 33sb″. A second drain interconnection 45d″, a second gate interconnection 45n, and a source/bulk interconnection 45sb″ may be disposed on the insulating layer 43. The second drain interconnection 45d″ may pass through the insulating layer 43 to be electrically connected to the heavily-doped drain region 39d. The second gate interconnection 45n may pass through the insulating layer 43 to be electrically connected to the gate electrode 37n. The source/bulk interconnection 45sb″ may pass through the insulating layer 43 to be electrically connected to the source region 39s and the bulk pick-up region 41b.

The second drain interconnection 45d″ may be electrically connected with the first drain interconnection 45d′ of FIG. 8 to thereby constitute the first output terminal OT1 of FIG. 4, and the source/bulk interconnection 45sb″ may be grounded.

According to the exemplary embodiments of the present invention as described above, a reverse bias may be applied between a source terminal and a bulk terminal of a pull-up MOS transistor constituting output stages of an address driver. Thus, operation of parasitic bipolar transistors, in which the source and bulk terminals of the pull-up MOS transistor respectively function as an emitter and a base in charging and discharging modes, may be suppressed. As a result, in the charging and discharging modes, power consumption due to the output stages of the address driver may be significantly reduced, and a ground terminal of the address driver may be prevented from having an unstable potential due to the operations of the parasitic bipolar transistors.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An address driver, comprising:
an energy recovery circuit; and
an output stage connected to the energy recovery circuit, the output stage including a pull-up MOS transistor and a pull-down MOS transistor in series,
wherein a source terminal of the pull-up MOS transistor is connected to the the energy recovery circuit, and a bulk terminal of the pull-up MOS transistor is connected to a node providing a reverse bias between the source terminal and the bulk terminal of the pull-up MOS transistor.

2. The address driver as claimed in claim 1, wherein the pull-up MOS transistor is a p-channel MOS transistor and the pull-down MOS transistor is an n-channel MOS transistor.

3. The address driver as claimed in claim 2, wherein a drain terminal of the pull-up MOS transistor is electrically connected to a drain terminal of the pull-down MOS transistor to form an output terminal of the output stage.

4. The address driver as claimed in claim 2, wherein a source terminal of the pull-down MOS transistor is grounded.

5. The address driver as claimed in claim 2, wherein the node connected to the bulk terminal of the pull-up MOS transistor has a higher voltage than the source terminal of the pull-up MOS transistor.

6. The address driver as claimed in claim 2, wherein an output voltage of a power source supplying electrical power to the energy recovery circuit is higher than an output voltage of the energy recovery circuit, and the bulk terminal of the pull-up MOS transistor is electrically connected to the power source via the node.

7. The address driver as claimed in claim 1, wherein the energy recovery circuit comprises a resonance circuit connected to the energy recovery circuit.

8. An address driver, comprising:
a pull-up MOS transistor in a first region of a semiconductor substrate;
a pull-down MOS transistor in a second region of the semiconductor substrate;
an insulating layer covering the pull-up MOS transistor and the pull-down MOS transistor;
a first source interconnection on the insulating layer and electrically connected to a source region of the pull-up MOS transistor;
a first bulk interconnection on the insulating layer and electrically connected to a bulk region of the pull-up MOS transistor; and
an energy recovery circuit in a third region of the semiconductor substrate and electrically connected to the first source interconnection,
wherein the first bulk interconnection is electrically insulated from the first source interconnection.

9. The address driver as claimed in claim 8, further comprising:
a power line on the insulating layer to supply electrical power to the energy recovery circuit, wherein the first bulk interconnection is electrically connected to the power line.

10. The address drive as claimed in claim 8, wherein the pull-up MOS transistor and the pull-down MOS transistor are a p-channel MOS transistor and an n-channel MOS transistor, respectively.

11. The address driver as claimed in claim 10, wherein:
the semiconductor substrate comprises a p-type supporting substrate and an n-type body layer disposed on the p-type supporting substrate;
the pull-up MOS transistor includes:
a p-type diffusion isolation region in a predetermined region of the n-type body layer and electrically isolating a part of the n-type body layer,
a p-type drain region in the isolated n-type body layer,
a p-type source region in the isolated n-type body layer and spaced apart from the p-type drain region,
an n-type bulk pick-up region in the isolated n-type body layer between the p-type diffusion isolation region and the p-type source region, and the isolated n-type body layer between the p-type diffusion region and the p-type drain region, and
a gate electrode disposed on the isolated n-type body layer between the p-type source and drain regions, and
the first source interconnection is electrically connected to the p-type source region through the insulating layer, and the first bulk interconnection is electrically connected to the n-type bulk pick-up region through the insulating layer.

12. The address driver as claimed in claim 11, wherein the p-type diffusion isolation region is in contact with the p-type supporting substrate.

13. The address driver as claimed in claim 11, further comprising:
an n-type buried layer between the isolated n-type body layer and the p-type supporting substrate, wherein the n-type buried layer has a higher impurity concentration than the n-type body layer.

14. The address driver as claimed in claim 11, wherein the pull-up MOS transistor has a symmetrical structure with respect to a vertical axis passing through a central point of the isolated n-type body layer between the p-type source region and the p-type drain region.

15. The address driver as claimed in claim 11, further comprising:
a first drain interconnection on the insulating layer and electrically connected to the p-type drain region of the pull-up MOS transistor; and
a second drain interconnection on the insulating layer and electrically connected to the drain region of the pull-down MOS transistor,
wherein the first and second drain interconnections are electrically connected to each other to serve as an output terminal of an output stage including the pull-up MOS transistor and the pull-down MOS transistor.

16. A display device, comprising:
a display panel having a plurality of pixels two-dimensionally disposed along rows and columns, a scanning driver and an address driver configured to sequentially provide an image signal to the plurality of pixels, and a display controller configured to control the scanning driver and the address driver,
wherein the address driver includes:
an energy recovery circuit generating a charge signal or a discharge signal in response to an output signal of the display controller; and
a plurality of output stages parallel-connected to the energy recovery circuit, each stage having a pull-up MOS transistor and a pull-down MOS transistor in series,
each output stage including an output terminal connected to one of the columns, source terminals of the pull-up MOS transistors are connected to the energy recovery circuit, and bulk terminals of the pull-up MOS transistors are connected to a node providing a reverse bias between the source terminals and the bulk terminals of the pull-up MOS transistors.

17. The display device as claimed in claim 16, wherein the display panel is a plasma display panel (PDP).

18. A display device, comprising:
a display panel having a plurality of pixels, and a scanning driver and an address driver configured to sequentially provide a charge signal or a discharge signal to the plurality of pixels, the address driver including an energy recovery circuit having a resonance circuit configured to generate the charge signal or the discharge signal, and a plurality of output stages parallel-connected to the energy recovery circuit,
wherein each output stage includes:
a pull-up MOS transistor on a semiconductor substrate and having a first source region electrically connected to the energy recovery circuit;
a pull-down MOS transistor on the semiconductor substrate and having a second drain region electrically connected to a first drain region of the pull-up MOS transistor;
an insulating layer covering the pull-up MOS transistor and the pull-down MOS transistor;
a first source interconnection on the insulating layer and electrically connected to the first source region; and
a first bulk interconnection on the insulating layer and electrically connected to the first bulk region of the pull-up MOS transistor, the first source interconnection being electrically insulated from the first bulk interconnection.

19. The display device as claimed in claim 18, wherein the display panel is a plasma display panel (PDP).

20. A method of making an address driver, comprising:
forming a pull-up MOS transistor in a first region of a semiconductor substrate;
forming a pull-down MOS transistor in a second region of the semiconductor substrate;
forming an insulating layer covering the pull-up MOS transistor and the pull-down MOS transistor;
forming a first source interconnection on the insulating layer and electrically connected to a source region of the pull-up MOS transistor;
forming a first bulk interconnection on the insulating layer and electrically connected to a bulk region of the pull-up MOS transistor; and
forming an energy recovery circuit in a third region of the semiconductor substrate and having an output terminal electrically connected to the first source interconnection,
wherein the first bulk interconnection is electrically insulated from the first source interconnection.
